(19) United States
(12) Patent Application Publication
(10) Pub. No.: US 2026/0214959 A1
(43) Pub. Date: Jul. 23, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Tatsuya HASHIMOTO, Azumino-city (JP)

(73) Assignee: FUJI ELECTRIC CO., LTD., Kawasaki-shi (JP)

(21) Appl. No.: 19/403,691

(22) Filed: Nov. 28, 2025

(30) Foreign Application Priority Data
Jan. 21, 2025 (JP) 2025-008779

(51) Int. Cl. H10D 64/23; H10D 12/00; H10D 12/01

(52) U.S. Cl. CPC H10D 64/232; H10D 12/038; H10D 12/481

(57) ABSTRACT

A semiconductor device includes a semiconductor substrate of a first conductivity type, a first semiconductor region of a second conductivity type, a plurality of second semiconductor regions of the first conductivity type, a plurality of trenches, a plurality of gate dielectrics, a plurality of gate electrodes, an oxide film covering the gate electrodes and the plurality of second semiconductor regions, a silicon nitride film provided on the oxide film, an interlayer dielectric film provided on the silicon nitride film, a plurality of contact vias, a barrier layer, a metal plug layer, a first electrode, and a second electrode.

### CROSS REFERENCE TO RELATED APPLICATIONS

This application is based upon and claims the benefit of priority of the prior Japanese Patent Application No. 2025-008779, filed on January 21, 2025, the entire contents of which are incorporated herein by reference.

### BACKGROUND OF THE INVENTION

### Field of the Invention

Embodiments of the disclosure relate to a semiconductor device and a method of manufacturing a semiconductor device.

### Description of the Related Art

A known semiconductor device ensures a short margin between a contact and a gate electrodes and the suppresses short circuit between the contact and the gate electrodes even when a contact hole formed by a self-alignment technique is formed at a position deviated from a predetermined position. For example, refer to Japanese Laid-Open Patent Publication No. 2014-175647.

### SUMMARY OF THE INVENTION

A semiconductor device according to an embodiment of the present disclosure includes: a semiconductor substrate of a first conductivity type, the semiconductor substrate having a first surface and a second surface opposite to each other; a first semiconductor region of a second conductivity type, provided at the first surface of the semiconductor substrate, the first semiconductor region having a first surface and a second surface opposite to each other, the second surface thereof facing the semiconductor substrate; a plurality of second semiconductor regions of the first conductivity type, selectively provided in the first semiconductor region, at the first surface thereof; a plurality of trenches penetrating through the first semiconductor region and the plurality of second semiconductor regions and reaching the semiconductor substrate; a plurality of gate dielectrics provided in the plurality of trenches, respectively, along bottom surfaces and sidewalls of the plurality of trenches; a plurality of gate electrodes provided on the plurality of gate dielectrics in the plurality of trenches, respectively; an oxide film covering the plurality of gate electrodes and the plurality of second semiconductor regions; a silicon nitride film provided on the oxide film; an interlayer dielectric film provided on the silicon nitride film; a plurality of contact vias penetrating through the oxide film, the silicon nitride film, and the interlayer dielectric film, and reaching the first semiconductor region; a barrier layer provided on sidewalls and bottom surfaces of the plurality of contact vias; a metal plug layer provided in the plurality of contact vias and in contact with the barrier layer; a first electrode provided on surfaces of the metal plug layer and the interlayer dielectric film; and a second electrode provided at the second surface of the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 2 is a flowchart of forming a structure in a vicinity of a trench-type gate of a cell portion in the method of manufacturing the semiconductor device according to the embodiment.

FIG. 3 is a cross-sectional view schematically depicting formation of the structure of a vicinity of a trench-type gate of a cell portion in a method of manufacturing the semiconductor device according to the embodiment.

FIG. 4 is a cross-sectional view schematically depicting formation of the structure of a vicinity of a trench-type gate of a cell portion in a method of manufacturing the semiconductor device according to the embodiment.

FIG. 5 is a cross-sectional view schematically depicting formation of the structure of a vicinity of a trench-type gate of a cell portion in a method of manufacturing the semiconductor device according to the embodiment.

FIG. 6 is a cross-sectional view schematically depicting formation of the structure of a vicinity of a trench-type gate of a cell portion in a method of manufacturing the semiconductor device according to the embodiment.

FIG. 7 is a cross-sectional view schematically depicting formation of the structure of a vicinity of a trench-type gate of a cell portion in a method of manufacturing the semiconductor device according to the embodiment.

FIG. 7A is a cross-sectional view along cutting line A-A′ in FIG. 7C schematically depicting formation of the structure in a vicinity of the trench-type gate of the cell portion in the method of manufacturing the semiconductor device according to the embodiment.

FIG. 7B is a cross-sectional view along cutting line B-B′ in FIG. 7C schematically depicting formation of the structure in a vicinity of the trench-type gate of the cell portion in the method of manufacturing the semiconductor device according to the embodiment.

FIG. 7C is a plan view of FIGS. 7A and 7B in the method of manufacturing the semiconductor device according to the embodiment.

FIG. 8 is a cross-sectional view schematically depicting formation of the structure of a vicinity of a trench-type gate of a cell portion in a method of manufacturing the semiconductor device according to the embodiment.

FIG. 9 is a cross-sectional view schematically depicting formation of the structure of a vicinity of a trench-type gate of a cell portion in a method of manufacturing the semiconductor device according to the embodiment.

FIG. 10 is a cross-sectional view schematically depicting formation of the structure of a vicinity of a trench-type gate of a cell portion in a method of manufacturing the semiconductor device according to the embodiment.

FIG. 11 is a cross-sectional view schematically depicting formation of the structure of a vicinity of a trench-type gate of a cell portion in a method of manufacturing the semiconductor device according to the embodiment.

FIG. 12 is a cross-sectional view schematically depicting formation of the structure of a vicinity of a trench-type gate of a cell portion in a method of manufacturing the semiconductor device according to the embodiment.

FIG. 13 is a cross-sectional view schematically depicting formation of the structure of a vicinity of a trench-type gate of a cell portion in a method of manufacturing the semiconductor device according to the embodiment.

FIG. 14 is a cross-sectional view schematically depicting formation of the structure of a vicinity of a trench-type gate of a cell portion in a method of manufacturing the semiconductor device according to the embodiment.

FIG. 15 is a graph depicting the frequency of misalignment of centers of gate trenches in the semiconductor device according to the embodiment and a conventional semiconductor device.

FIG. 16 is a cross-sectional view depicting a structure of the conventional semiconductor device.

FIG. 17 is a cross-sectional view schematically depicting formation of a structure of a vicinity of a trench-type gate of a cell portion in a method of manufacturing the conventional semiconductor device.

FIG. 18 is a cross-sectional view schematically depicting formation of a structure of a vicinity of a trench-type gate of a cell portion in the method of manufacturing the conventional semiconductor device.

FIG. 19 is a cross-sectional view schematically depicting formation of a structure of a vicinity of a trench-type gate of a cell portion in the method of manufacturing the conventional semiconductor device.

FIG. 20 is a cross-sectional view schematically depicting misalignment in the formation of a structure in a vicinity the trench-type gate in a cell portion in the method of manufacturing the conventional semiconductor device.

FIG. 21 is a cross-sectional view schematically depicting misalignment in the formation of a structure in a vicinity the trench-type gate in a cell portion in the method of manufacturing the conventional semiconductor device.

### DETAILED DESCRIPTION OF THE INVENTION

First, problems associated with the conventional techniques are discussed. The formation of a contact vias that does not short-circuit the trenches gate portion has a problem in that the positional accuracy of exposure at the time of contact formation determines a limit.

An overview of an embodiment of the present disclosure is described. A semiconductor device according to the present disclosure has the following features. A first semiconductor region of a second conductivity type is provided at a front surface of a semiconductor substrate of a first conductivity type. A plurality of second semiconductor regions of the first conductivity type is selectively provided in the first semiconductor region, at a first surface thereof opposite to a second surface thereof facing the semiconductor substrate. A plurality of trenches penetrating through the first semiconductor region and the plurality of second semiconductor regions and reaching the semiconductor substrate is provided. A plurality of gate dielectrics is provided in the plurality of trenches along bottom portions and sidewalls of the plurality of trenches. A plurality of gate electrodes is provided in the gate dielectrics in the trenches. An oxide film covering the gate electrodes and the plurality of second semiconductor regions is provided. A silicon nitride film is provided on the oxide film. An interlayer dielectric film is provided on the silicon nitride film. A plurality of contact vias penetrating the oxide film, the silicon nitride film, and the interlayer dielectric film and reaching the first semiconductor region is provided. A barrier layer is provided at sidewalls and a bottom surface of the contact vias. A metal plug layer is provided in the contact vias, in contact with the barrier layer. A first electrode is provided on surfaces of the metal plug layer and the interlayer dielectric film. A second electrode is provided at a back side of the semiconductor substrate.

According to the above disclosure, the oxide film is provided on the gate electrodes and the plurality of second semiconductor regions (n⁺-type emitter regions) of the first conductivity type, and the silicon nitride film is provided on the oxide film. Due to the silicon nitride film, even when the positional accuracy of the photoresist at the time of forming the contact vias and at the time of forming the contacts is insufficient, the contact vias may be formed between the gate trenches in a self-aligned manner without short-circuiting to the gate trenches, and it is possible to reduce the deterioration of the positional accuracy of the contact vias and the occurrence of fluctuation of characteristics.

In the semiconductor device according to the present disclosure, the plurality of gate electrodes may protrude from the plurality of second semiconductor regions toward the first electrode, and the silicon nitride film may be provided to cover protruding portions of the gate electrodes.

A method of manufacturing a semiconductor device according to the present disclosure that solves the problems above has the following features. First, a first process of forming a plurality of trenches in a semiconductor substrate of a first conductivity type, at a front surface thereof is performed. Next, a second process of forming a plurality of gate dielectrics in the trenches along bottoms and sidewalls of the plurality of trenches is performed. Next, a third process of forming a plurality of gate electrodes on the plurality of gate dielectrics in the trenches is performed. Next, a fourth process of selectively forming a first semiconductor region of a second conductivity type at the front surface of the semiconductor substrate is performed. Next, a fifth process of selectively forming a plurality of second semiconductor regions of the first conductivity type in the first semiconductor region, at a first surface thereof opposite to a second surface thereof facing the semiconductor substrate is performed. Next, a sixth process of forming an oxide film covering the plurality of gate electrodes and the plurality of second semiconductor regions is performed. Next, a seventh process of forming a silicon nitride film covering the oxide film is performed. Next, an eighth process of forming an interlayer dielectric film covering the silicon nitride film is performed. Next, a ninth process of forming a plurality of contact vias penetrating the interlayer dielectric film and the silicon nitride film and reaching the first semiconductor region is performed. Next, a tenth process of forming a barrier layer at sidewalls and bottom surfaces of the plurality of contact vias is performed. Next, an eleventh process of forming a metal plug layer in contact with the barrier layer in the plurality of contact vias is performed. Next, a twelfth process of forming a first electrode on the surfaces of the metal plug layer and the interlayer dielectric film is performed. Next, a thirteenth process of forming a second electrode at a back surface of the semiconductor substrate is performed.

In the method of manufacturing a semiconductor device according to the present disclosure, in the third process, the plurality of gate electrodes may be formed to protrude from the plurality of second semiconductor regions toward the first electrode, and in the seventh process, the silicon nitride film may be formed to cover protruding portions of the gate electrodes.

In the method of manufacturing a semiconductor device according to the present disclosure, the method further includes a fourteenth process of forming a thermal oxide film and a nitride film on the semiconductor substrate before the first process.

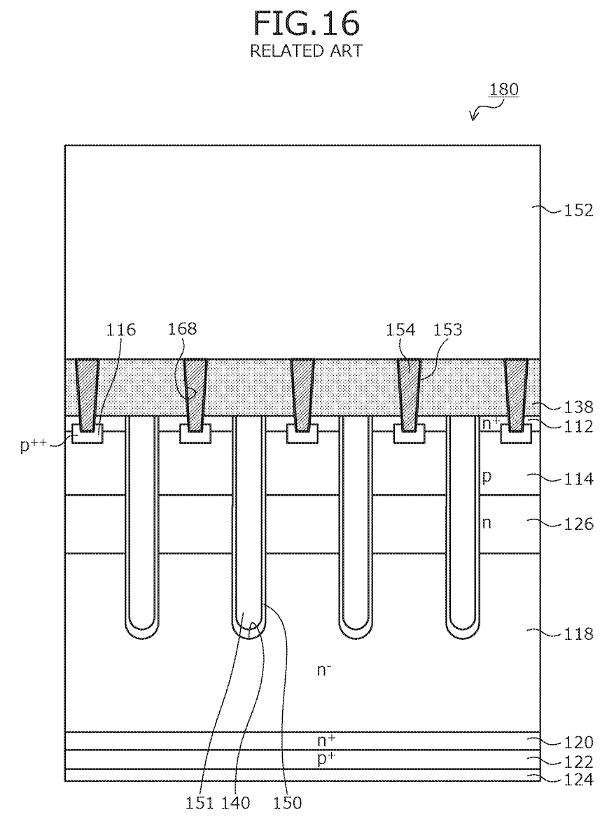

Findings underlying the present disclosure. First, problems of the conventional semiconductor device will be discussed. An insulated gate bipolar transistor (IGBT) is described as an example of a conventional semiconductor device. FIG. 16 is a cross-sectional view depicting a structure of a conventional semiconductor device. The conventional semiconductor device depicted in FIG. 16 is an IGBT 180 having a trench gate structure.

In the IGBT 180, an n-type CS layer 126 is provided in a surface layer of a front surface of an n⁻-type semiconductor substrate (silicon semiconductor substrate) 118 serving as an n⁻-type drift layer. The n-type CS layer may be omitted. The p-type base region 114 is provided on the n-type CS layer 126. The p-type base region 114 functions as a channel region in the IGBT 180. Gate trenches 140 penetrating through the p-type base region 114 and reaching the n⁻-type semiconductor substrate 118 are provided. On both sides of each of the gate trenches 140, n⁺-type emitter regions 112 are provided. In the gate trenches 140, gate dielectrics 150 are provided respectively, along inner walls of the gate trenches 140, and gate electrodes 151 are provided respectively on the gate dielectrics 150.

The emitter electrode 152 is in contact with the n⁺-type emitter regions 112 through contact vias 168, and is electrically insulated from the gate electrodes 151 by an interlayer dielectric film 138. An opening may be selectively provided in the n⁺-type emitter regions 112, and the emitter electrode 152 and the p-type base region 114 may be electrically connected to each other in the opening. Between the emitter electrode 152 and the interlayer dielectric film 138, for example, a barrier metal 153 for preventing diffusion of metal atoms from the emitter electrode 152 to the gate electrodes 151 is provided.

The contact electrodes 154 may be embedded in the contact vias 168 formed in the interlayer dielectric film 138. The contact electrodes 154 are, for example, a metal film containing tungsten (W), which as high embeddability. In the n⁺-type emitter regions 112, p⁺⁺-type contact regions 116 may be provided in contact with the contact vias 168. A protective film (not depicted) such as a passivation film containing, for example, a polyimide is selectively provided on the emitter electrode 152.

In the n⁻-type semiconductor substrate 118, an n⁺-type field stop (FS) layer 120 is provided in the substrate, at the back surface thereof. A p⁺-type collector region 122 is provided at a position shallower than is the n⁺-type FS layer 120 from the back surface of the n⁻-type semiconductor substrate 118. A back surface electrode 124 is provided at the surface of the p⁺-type collector region 122 (the entire back surface of the n⁻-type semiconductor substrate 118). The back surface electrode 124 functions as a collector electrode.

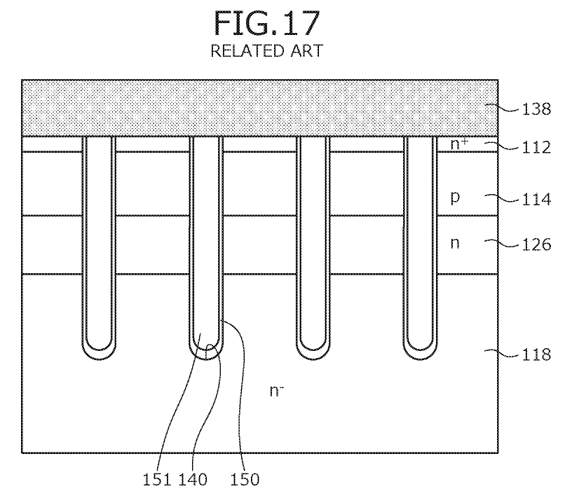

The conventional semiconductor device is manufactured, for example, as follows. FIGS. 17, 18, and 19 are cross-sectional views schematically depicting formation of a structure of a vicinity of a trench-type gate of a cell portion in a method of manufacturing the conventional semiconductor device. First, the n-type CS layer 126 is formed by, for example, an ion implantation method or epitaxial growth, at the front surface of the n⁻-type semiconductor substrate 118 constituting the n-type drift layer. Next, the gate trenches 140, the gate dielectrics 150, and the gate electrodes 151 are sequentially formed by a general method thereby forming MOS gates.

Next, the p-type base region 114 is formed by ion implantation of a p-type dopant, at a depth shallower than is the n-type CS layer 126 from the front surface of the n⁻-type semiconductor substrate 118. Next, the n⁺-type emitter regions 112 are selectively formed by ion implantation of an n-type dopant, in the p-type base region 114, at the surface thereof. Next, the interlayer dielectric film 138 such as an HTO film and a BPSG film is deposited (formed) so as to cover the gate electrodes 151. The state up to here is depicted in FIG. 17.

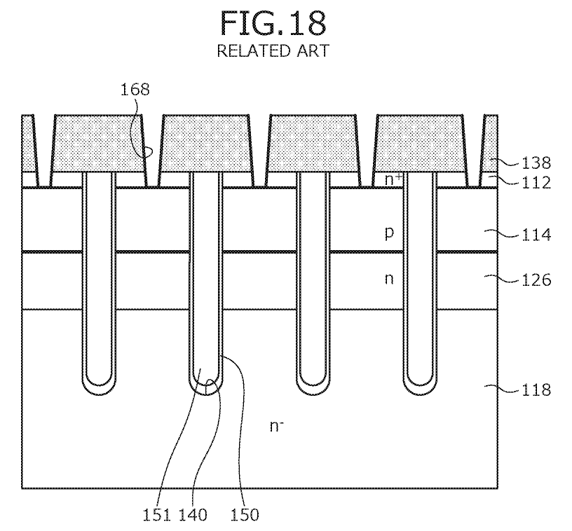

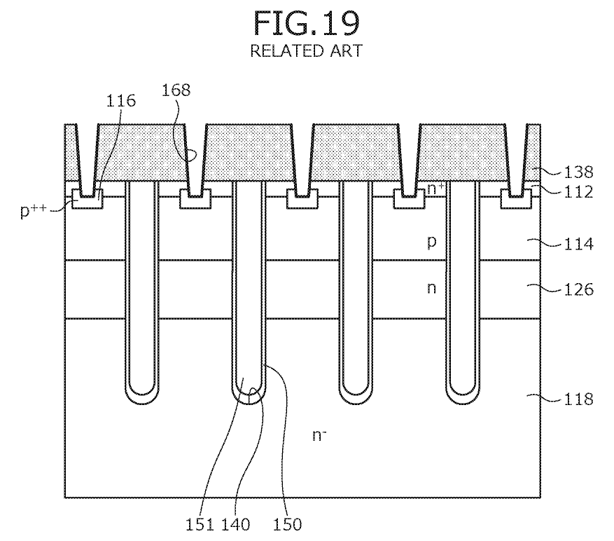

Next, the interlayer dielectric film 138 is patterned thereby forming the contact vias 168 for conduction with the emitter electrode 152 so as not to be short-circuited to the gate electrodes 151, and exposing the n⁺-type emitter regions 112. The state up to here is depicted in FIG. 18. Next, the p⁺⁺-type contact regions 116 are formed at the bottom portions of the contact vias 168 by ion implantation of a p-type dopant. The state up to here is depicted in FIG. 19.

Next, the contact electrodes 154 are formed in the contact vias 168 via the barrier metal 153. Next, the emitter electrode 152 covering the entire surface of the interlayer dielectric film 138 is formed by, for example, a sputtering method so as to be in contact with the contact electrodes 154 in the contact vias 168. As described, the front surface element structure of the conventional semiconductor device is formed.

Next, the n⁻-type semiconductor substrate 118 is ground from the back surface thereof to a position of a product thickness used for the semiconductor device. Next, an n-type dopant is ion-implanted into the entire back surface of the n⁻-type semiconductor substrate 118 thereby forming the n⁺-type FS layer 120 in the n⁻-type semiconductor substrate 118. Next, a p-type dopant is ion-implanted into the entire back surface of the n⁻-type semiconductor substrate 118 thereby forming the p⁺-type collector region 122 in the n⁻-type semiconductor substrate 118, at the entire back surface thereof.

Next, the p⁺-type collector region 122 and the n⁺-type FS layer 120 are activated by a heat treatment (annealing). Next, the entire front surface of the substrate is covered with a surface protective film (not depicted) such as a polyimide film and thereafter, the surface protective film is patterned thereby exposing the emitter electrode 152 and each electrode pad.

Next, the back surface electrode 124 in contact with the p⁺-type collector region 122 is formed in an entire of the back surface of the semiconductor substrate. Thereafter, the semiconductor wafer is cut (diced) into individual chips, whereby the IGBT 180 depicted in FIG. 16 is completed.

However, the conventional IGBT having a trench gate structure has been developed in the direction of lowering Von to reduce steady loss. To

reduce the Von, successive generations of technology have focused on making the device (chip) thinner and developing more compact and densely packed cell structures. Currently, one way to achieve denser cell structures is by using shorter wavelengths in the exposure machine, which allows for finer patterning. However, reducing the wavelength of the exposure machine requires investment and may lead to issues such as an inability to fully amortize the cost of older generation equipment. Therefore, to manufacture increasingly smaller structures, it is necessary to utilize older generation exposure machines as much as possible. Older generation exposure machines perform alignment optically and mechanically with limited accuracy. Therefore, a slight deviation in accuracy causes a defect in the characteristics .

In the method of manufacturing the conventional semiconductor device, the technique of forming the contact vias 168 so as not to short-circuit the gate electrodes 151 and the emitter electrode 152 is limited by the alignment accuracy of the exposure machine and the distortion of the pattern. The alignment accuracy at the time of exposure is determined by the stage feed accuracy of the exposure machine and the resolution of the optical system, and the limits of miniaturization have been determined with consideration of variations thereof.

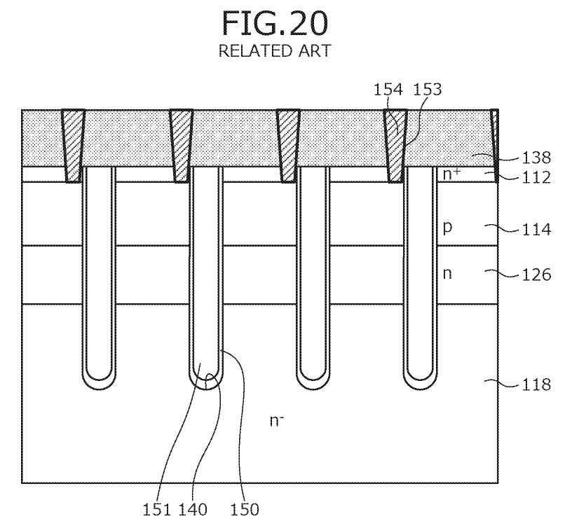

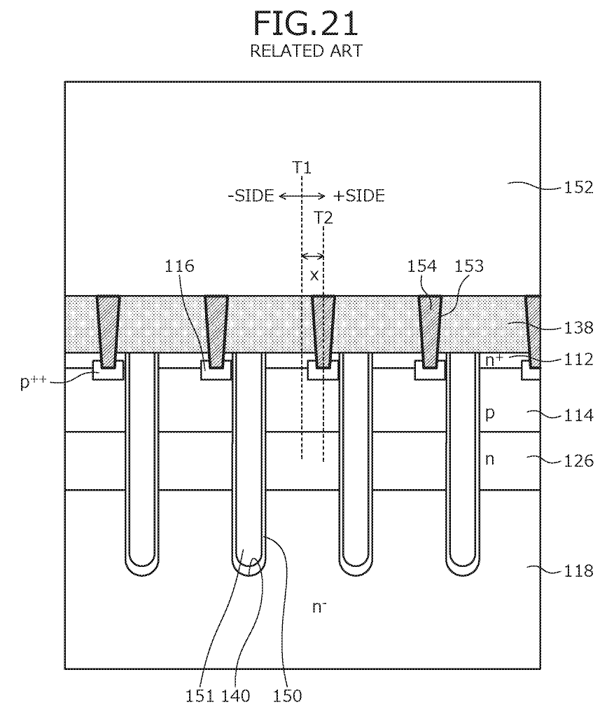

FIGS. 20 and 21 are cross-sectional views schematically depicting misalignment in the formation of a structure in a vicinity the trench-type gate in a cell portion in the method of manufacturing the conventional semiconductor device. FIG. 20 depicts a case where the gate electrodes 151 and the emitter electrode 152 are short-circuited, and FIG. 21 depicts a case where the positional accuracy of the contact vias 168 is poor. In addition, when there is distortion in the device pattern on the substrate side (wafer), there is a problem in that the center of alignment cannot be set in the entire region to be exposed.

As described above, in the method of manufacturing a conventional semiconductor device, when the limit of miniaturization is exceeded, there is a problem in that the gate electrodes 151 and the emitter electrode 152 may be short-circuited, the positional accuracy of the contact vias 168 may be deteriorated, and variation of the characteristics may be caused.

Here, preferred embodiments of a semiconductor device and a method of manufacturing a semiconductor device according to the present disclosure are described in detail with reference to the accompanying drawings. In the present specification and the accompanying drawings, layers and regions prefixed with n or p mean that majority carriers are electrons or holes, respectively. Further, + and − appended to n and p mean that the dopant concentration is higher or lower, respectively, than layers and regions without + and −. In the following description of the embodiments and the accompanying drawings, the same components are denoted by the same reference numerals, and redundant description thereof will be omitted. The term “the same ” or“ equivalent ” preferably includes 5% or less with consideration of manufacturing variations.

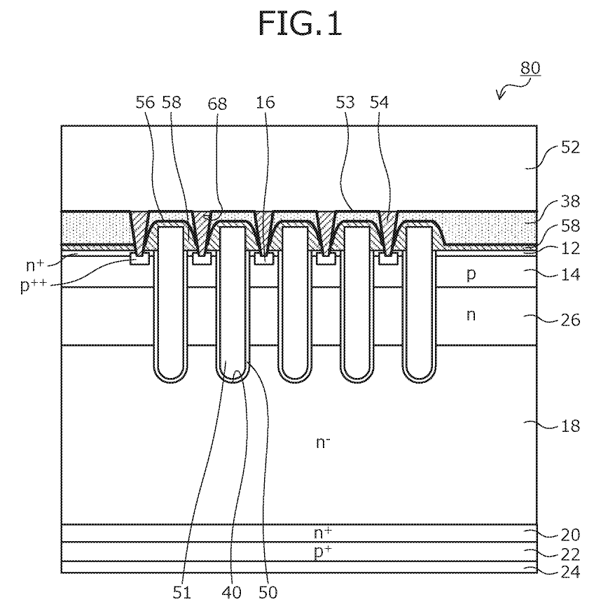

A structure of a semiconductor device according to an embodiment will be described using an IGBT as an example. FIG. 1 is a cross-sectional view depicting a structure of a semiconductor device according to an embodiment. The semiconductor device according to the embodiment depicted in FIG. 1 is an IGBT 80 having a trench gate structure. FIG. 1 depicts a structure of an active region through which a current flows during an ON state.

In the IGBT 80, an n-type CS layer 26 may be provided in an n⁻-type semiconductor substrate (a silicon semiconductor substrate, a semiconductor substrate of a first conductivity type) 18, at a front surface thereof, the n⁻-type semiconductor substrate 18 constituting an n⁻-type drift layer. The n-type CS layer 26 may be omitted. The n-type CS layer 26 is a so-called carrier storage layer that reduces spreading resistance of carriers. A p-type base region (first semiconductor region of the second conductivity type) 14 is provided on the n-type CS layer 26 (the front surface side of the n⁻-type semiconductor substrate 18). The p-type base region 14 functions as a channel region in the IGBT 80. Gate trenches 40 penetrating through the p-type base region 14 and reaching the n⁻-type semiconductor substrate 18 are provided. On both sides of each of the gate trenches 40, n⁺-type emitter regions 12 are disposed, the gate trenches 40 being in a planar layout of, for example, a stripe shape at a predetermined interval, and separates the p-type base region 14 into a plurality of regions (mesa portions). Inside the gate trenches 40, gate dielectrics 50 are provided along the inner wall of the gate trenches 40, and gate electrodes 51 are provided in the gate dielectrics 50. In the embodiment, a part of the gate electrodes 51 protrudes from above the gate trenches 40 (a side on which an emitter electrode 52 to be described later is provided) toward the emitter electrode 52.

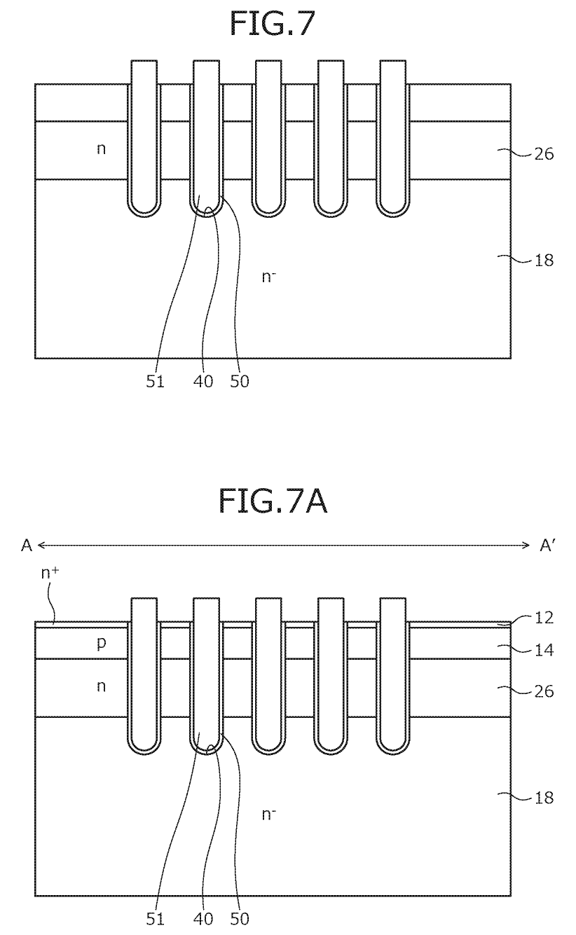

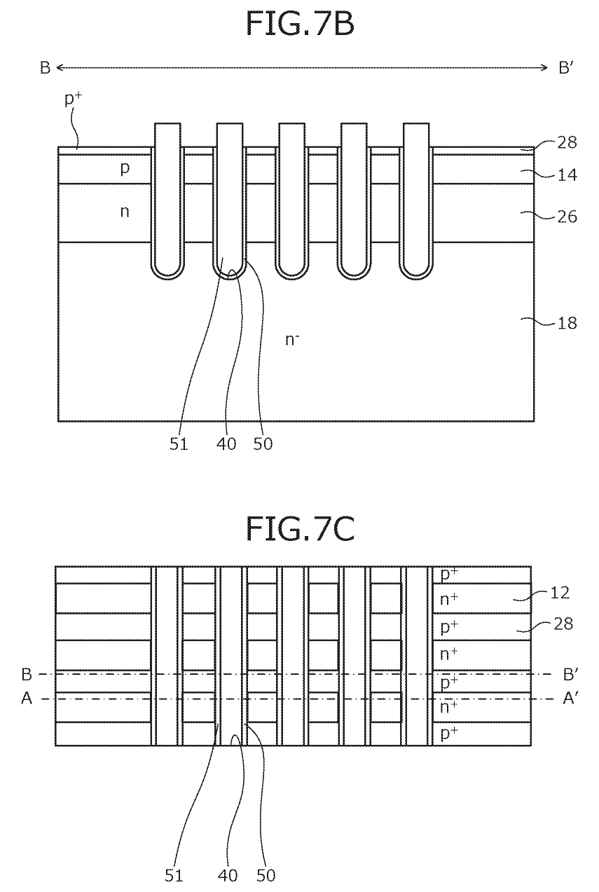

In the p-type base region 14, n⁺-type emitter regions (second semiconductor regions of the first conductivity type) 12 are selectively provided in the mesa portions. The n⁺-type emitter regions 12 face the gate electrodes 51 across the gate dielectrics 50 provided at the inner walls of the gate trenches 40. In the p-type base region 14, p⁺-type emitter regions 28 may be provided in mesa portions. In a top view, the n⁺-type emitter regions 12 and the p⁺-type emitter regions 28 may be provided alternating each other so as to intersect the gate trenches 40 in a direction in which the gate trenches 40 extend in the depth direction (see FIG. 7C).

In the embodiment, an oxide film 58 and a silicon nitride film (SiN) 59[R]56 are formed on the n⁺-type emitter regions 12. The silicon nitride film 56 and the interlayer dielectric film 38 are provided in this order. The emitter electrode (first electrode) 52 is in contact with the n⁺-type emitter regions 12 through the contact vias 68, and is electrically insulated from the gate electrodes 51 by the oxide film 58, the silicon nitride film 56, and the interlayer dielectric film 38.

The oxide film 58 is a SiO₂ film formed by, for example, a CVD method, and is provided on the gate electrodes 51 and the n⁺-type emitter regions 12. The silicon nitride film 56 is a SiN film formed by, for example, a CVD method, and is provided on the oxide film 58. The silicon nitride film 56 has a film thickness of about 0.2 μm and is provided so as to cover a portion of the gate electrodes 51 protruding above the gate trenches 40. The silicon nitride film 56 is structured to be self-aligned at the time of forming the contact vias 68, and the contact vias 68 may be formed in the middle between the gate trenches 40 without affecting the alignment accuracy at the time of contact exposure and the distortion of the gate trenches pattern.

The interlayer dielectric film 38 has two layers including a high temperature oxide (HTO) and boron phosphorus silicon glass (BPSG). The interlayer dielectric film 38 is provided on the silicon nitride film 56 and has a film thickness of about 0.5 μm. The contact vias 68 penetrate through the oxide film 58, the silicon nitride film 56, and the interlayer dielectric film 38 to reach the p-type base region 14.

An opening may be selectively provided in the n⁺-type emitter regions 12, and the emitter electrode 52 and the p-type base region 14 may be electrically connected to each other in the opening. Between the emitter electrode 52 and the interlayer dielectric film 38, for example, a barrier metal (barrier layer) 53 that prevents diffusion of metal atoms from the emitter electrode 52 to the gate electrodes 51 may be provided. The barrier metal 53 includes, for example, two layers including a titanium (Ti) layer and a titanium nitride (TiN) layer.

The contact electrodes (metal plug layer) 54 may be embedded in the contact vias 68 formed in the interlayer dielectric film 38. The contact electrodes 54 are, for example, a metal film containing tungsten (W), which has high embeddability. In the n⁺-type emitter regions 12, p⁺⁺-type contact regions 16 may be provided in contact with the contact vias 68. A protective film (not depicted) such as a passivation film containing, for example, polyimide is selectively provided on the emitter electrode 52.

In the n⁻-type semiconductor substrate 18, an n⁺-type field stop (FS) layer 20 is provided at the back surface of the substrate. The n⁺-type FS layer 20 has a function of suppressing the spreading of a depletion layer extending from pn junctions between the p-type base region 14 and the n⁻-type semiconductor substrate 18 in a direction to a p⁺-type collector region 22 described later, during an off state.

The p⁺-type collector region 22 is provided in the n⁻-type semiconductor substrate 18, at the back surface thereof, at a position shallower than is the n⁺-type FS layer 20 from the back surface of the n⁻-type semiconductor substrate 18. The back surface electrode (second electrode) 24 is provided at a surface of the p⁺-type collector region 22 (the entire back surface of the n⁻-type semiconductor substrate 18). The back surface electrode 24 functions as a collector electrode.

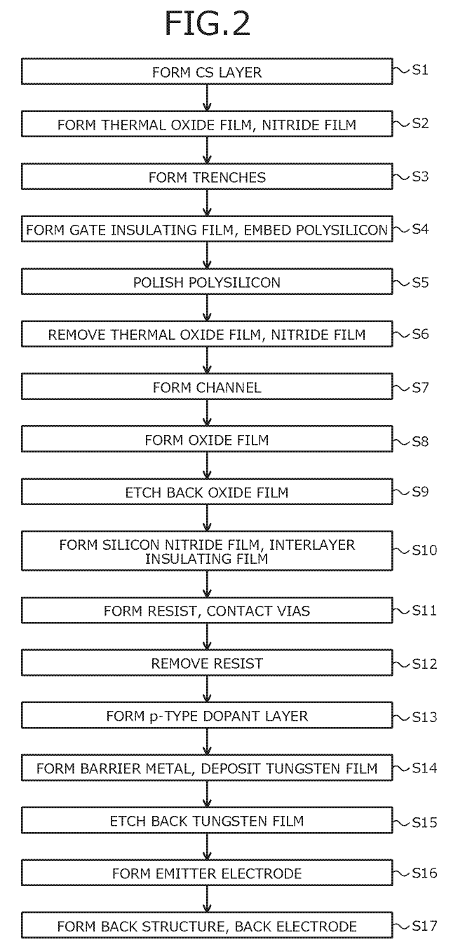

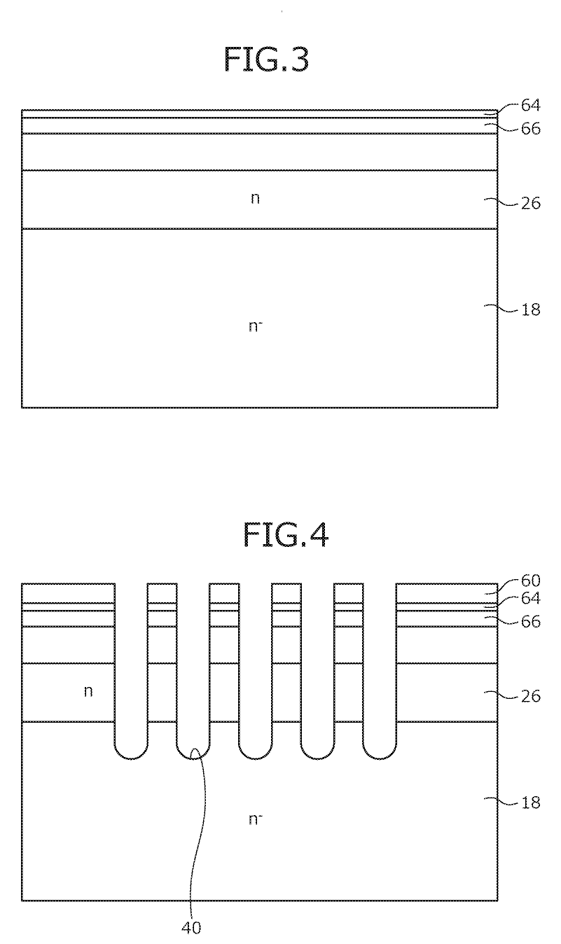

Next, a method of manufacturing the semiconductor device according to the embodiment will be described. FIG. 2 is a flowchart of forming a structure in a vicinity of a trench-type gate of a cell portion in the method of manufacturing the semiconductor device according to the embodiment. FIGS. 3, 4, 5, 6, 7, 8, 9, 10, 11, 12, 13, and 14 are cross-sectional views schematically depicting formation of the structure of a vicinity of a trench-type gate of a cell portion in the method of manufacturing the semiconductor device according to the embodiment. The semiconductor device according to the embodiment is manufactured, for example, as follows. First, the n-type CS layer 26 is formed by, for example, an ion implantation method or epitaxial growth at the front surface of the n⁻-type semiconductor substrate 18 constituting the n-type drift layer (step S1). When the n-type CS layer 26 is formed by the ion implantation method, the n-type CS layer 26 may be formed in the n⁻-type semiconductor substrate 18.

Next, when the n-type CS layer 26 is formed by an ion implantation method, the thermal oxide film 66 and the nitride film 64 are formed on the front surface of the semiconductor substrate 18 (step S2: fourteenth process). When the n-type CS layer 26 is formed by epitaxial growth, a thermal oxide film 66 and a nitride film 64 may be formed on the n-type CS layer 26. The state up to here is depicted in FIG. 3. The thermal oxide film 66 is, for example, a silicon oxide film (SiO₂), is formed on the n-type CS layer 26, and has a film thickness of about 0.5 μm. The nitride film 64 is, for example, a silicon nitride film (SiN), is formed by a chemical vapor deposition (CVD) method on the thermal oxide film 66, and has a film thickness of about 0.2 μm. The nitride film 64 may be omitted. However, it is preferable to form the nitride film 64 because etching by CMP is easily stopped at the nitride film 64 and the thermal oxide film 66 may be prevented from being etched.

Next, on the surface of the n⁻-type semiconductor substrate 18, a trench formation mask having predetermined openings is formed by photolithography using, for example, a photoresist 60. Next, the trenches 40 penetrating through the n-type CS layer 26 and reaching the n⁻-type semiconductor substrate 18 is formed by dry etching (step S3: first process). The state up to here is depicted in FIG. 4. Next, the trench formation mask is removed.

Next, the gate dielectrics 50 are formed along the bottom portions and the sidewalls of the trenches 40 (second process). The gate dielectrics 50 may be formed by thermal oxidation at a temperature of about 1000 degrees C under an oxygen atmosphere. Alternatively, the gate dielectrics 50 may be deposited by a chemical reaction such as that of a high temperature oxide (HTO).

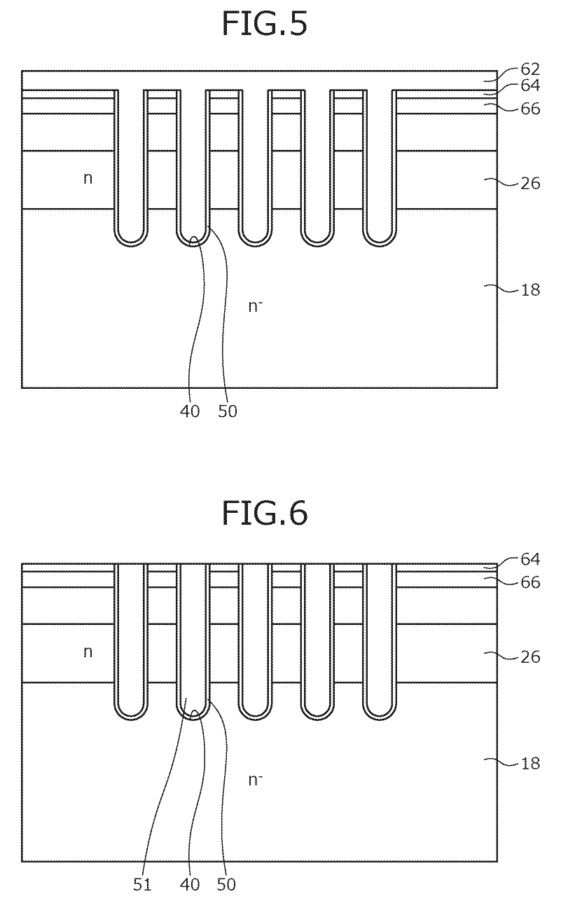

Next, a polysilicon 62 doped with, for example, phosphorus atoms is provided on the gate dielectrics 50. The polysilicon 62 is formed so as to be embedded in the trenches 40 (step S4). The state up to here is depicted in FIG. 5. The polysilicon 62 is polished back by chemical mechanical polishing (CMP) to be left in the trenches 40, thereby forming the gate electrodes 51 (step S5: third process). Alternatively, the polysilicon 62 may be removed by etching back the entire surface by dry etching. The state up to here is depicted in FIG. 6. Thus, the MOS gates are formed.

Next, the thermal oxide film 66 and the nitride film 64 are removed (step S6). The state up to here is depicted in FIG. 7. The nitride film 64 is removed by, for example, phosphoric acid boiling or the like, and the thermal oxide film 66 is removed by, for example, a hydrofluoric acid treatment or the like. By these removals, a portion of each of the gate electrodes 51 protrudes above the gate trenches 40.

Next, the channel of the IGBT 80 is formed (step S7: fourth process, fifth process). For example, the channel is formed as follows. By ion implantation of a p-type dopant, the p-type base region 14 is formed at a shallower depth from the front surface of the n⁻-type semiconductor substrate 18 than is the n-type CS layer 26. Here, FIG. 7A is a cross-sectional view along cutting line A-A′ in FIG. 7C schematically depicting formation of a structure in a vicinity of the trench-type gate of the cell portion in the method of manufacturing the semiconductor device according to the embodiment. FIG. 7B is a cross-sectional view along cutting line B-B′ in FIG. 7C schematically depicting formation of a structure in a vicinity of the trench-type gate of the cell portion in the method of manufacturing the semiconductor device according to the embodiment; FIG. 7C is a plan view of FIGS. 7A and 7B in the method of manufacturing the semiconductor device according to the embodiment. Next, the n⁺-type emitter regions 12 are selectively formed in the p-type base region 14, at the surface thereof by ion implantation of an n-type dopant. The state up to here is depicted in FIG. 7A. Next, the p⁺-type emitter regions 28 may be selectively formed in the p-type base region 14, at the surface thereof by ion implantation of a p-type dopant. The state up to here is depicted in FIG. 7B. At this time, as depicted in FIG. 7C, the n⁺-type emitter regions 12 and the p⁺-type emitter regions 28 are formed so as to alternately to intersect the gate trenches 40 in a direction in which the gate trenches 40 extend in the depth direction in a top view. The p-type base region 14 is formed with an dopant concentration of, for example, 1.0×10¹⁷atoms/cm³ or less, and the n⁺-type emitter regions 12 are formed with an dopant concentration of, for example, 1.0×10¹⁹atoms/cm³ or less. Next, the p-type base region 14, the p⁺-type emitter regions 28, and the n⁺-type emitter regions 12 are activated by a heat treatment (annealing).

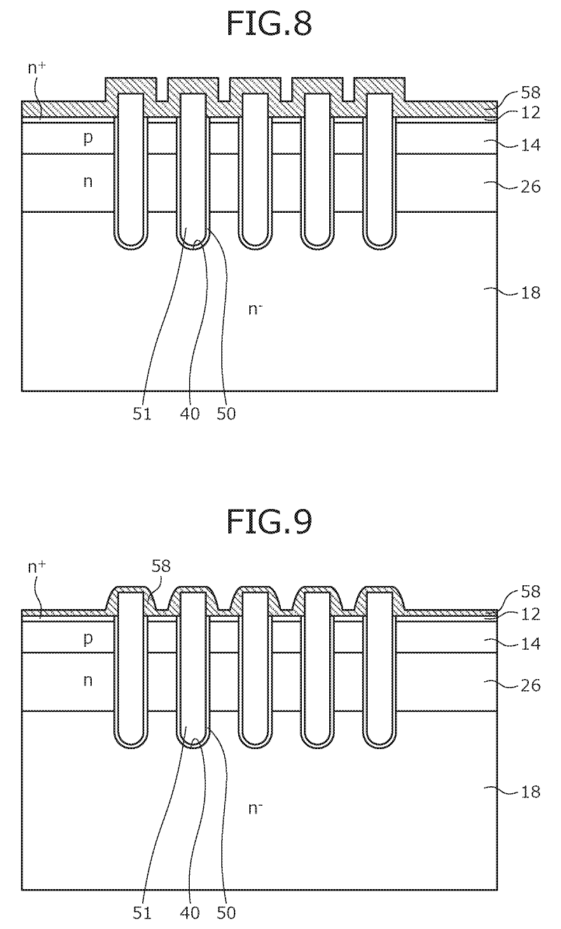

Next, the oxide film 58 is formed (step S8: sixth process). The state up to here is depicted in FIG. 8. For example, the oxide film 58 is formed by a CVD method on the n⁺-type emitter regions 12 and the gate electrodes 51 and has a film thickness of about 0.5 μm. Next, the oxide film 58 is etched back by, for example, HTO (step S9). This etch-back removes the corners of the oxide film 58 and makes the oxide film 58 thin. However, the oxide film 58 covers the n⁺-type emitter regions 12 and the gate electrodes 51, and a space for the contact vias 63 is formed between the gate trenches 40. The state up to here is depicted in FIG. 9.

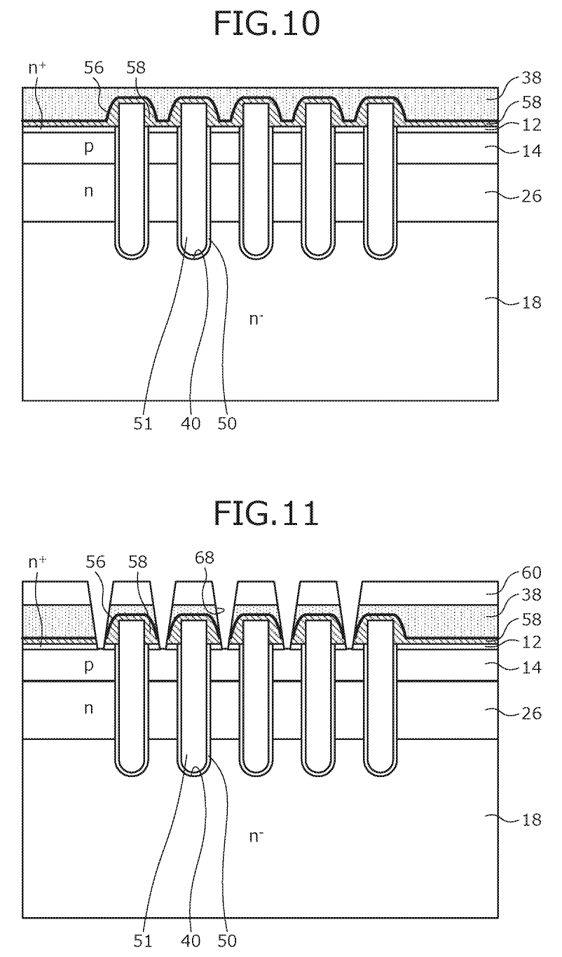

Next, the silicon nitride film 56 and the interlayer dielectric film 38 are formed (step S10: seventh process and eighth process). The state up to here is depicted in FIG. 10. For example, the silicon nitride film 56 contains SiN, is formed on the oxide film 58 by a CVD method, and has a film thickness of about 0.2 μm. For example, as the interlayer dielectric film 38, an HTO film having a thickness of about 0.1 μm is formed by CVD, and a BPSG film is grown thereon to a thickness of about 0.5 μm and is planarized. The planarization may be performed by reflow or by additionally growing an HTO film and polishing back the HTO film by CMP. Since the oxide film 58 is formed so as to cover the portions of the gate electrodes 51 protruding above the gate trenches 40, the silicon nitride film 56 is also formed so as to cover the portions of the gate electrodes 51 protruding above the gate trenches 40.

Next, the photoresist 60 is formed on the interlayer dielectric film 38 and the contact vias 68 are formed (step S11: ninth process). The state up to here is depicted in FIG. 11. At this time, even when the positional accuracy of the photoresist 60 at the time of contact formation is insufficient, the silicon nitride film 56 is hardly etched at the time of contact etching. Therefore, the contact vias 68 may be formed between the gate trenches 40 by self-alignment without short-circuiting to the gate trenches 40. Further, even when there is pattern distortion in the exposure shot, the contact vias 68 may be formed between the gate trenches 40 by self-alignment. Therefore, at the time of contact formation, the contact vias 68 may be formed between the gate trenches 40 by self-alignment even with a fine pattern of an optical resolution limit level.

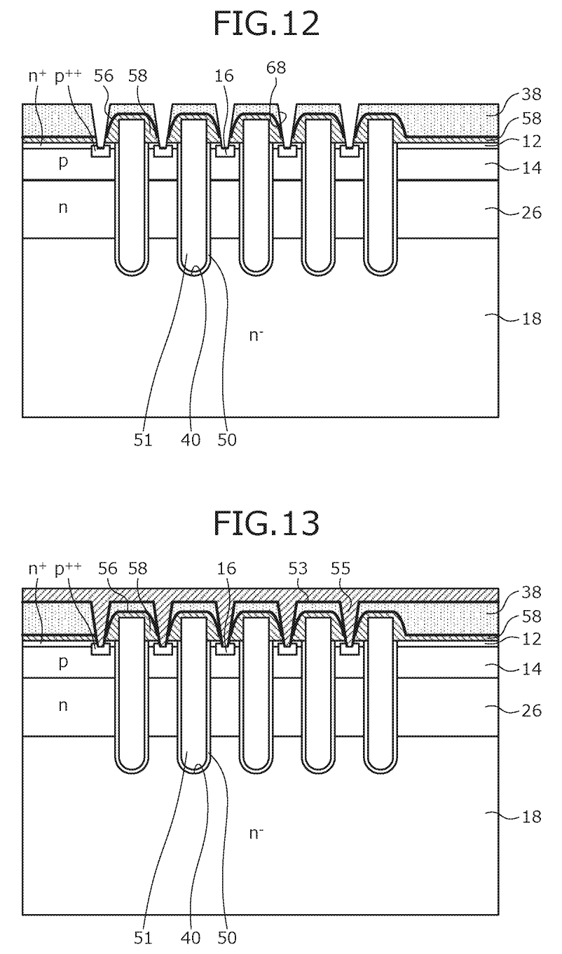

Next, the photoresist 60 is removed (step S12). For example, the photoresist 60 may be removed by ashing. Next, the p⁺⁺-type contact regions 16 are formed at the bottom portions of the contact vias 68 by ion implantation of a p-type dopant (step S13). The state up to here is depicted in FIG. 12. Next, the p⁺⁺-type contact regions 16 are activated by a heat treatment (annealing).

Next, the barrier metal 53 containing Ti and TiN is formed in the contact vias 68 (tenth process). For example, a Ti film is formed to have a film thickness of about 0.03 μm, and a TiN film is formed on the Ti film and has a film thickness of about 0.07 μm. Next, a tungsten film 55 is formed so as to be embedded in the contact vias 68 (step S14). The state up to here is depicted in FIG. 13. For example, the tungsten film 55 is formed to a thickness of about 0.5 μm.

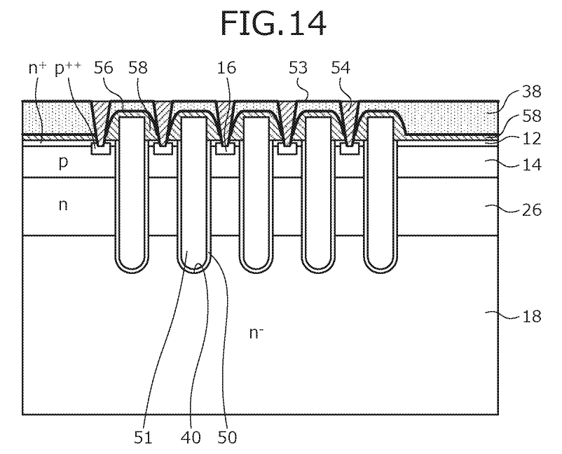

Next, the tungsten film 55 is etched back to form the contact electrodes 54 in the contact vias 68 (step S15: eleventh process). The state up to here is depicted in FIG. 14. The etch-back may be performed on the entire surface by the dry etching or may be performed by CMP. Next, the emitter electrode 52 covering the entire surface of the interlayer dielectric film 38 is formed (step S16: twelfth process). As described, the front device structure of the semiconductor device is formed.

Next, the n⁻-type semiconductor substrate 18 is ground from the back surface thereof to a position corresponding to a product thickness used for the semiconductor device. Next, an n-type dopant is ion-implanted into the entire back surface of the n⁻-type semiconductor substrate 18 thereby forming the n⁺-type FS layer 20 in the n⁻-type semiconductor substrate 18. Next, a p-type dopant is ion-implanted into the entire back surface of the n⁻-type semiconductor substrate 18 thereby forming the p⁺-type collector region 22 in the n⁻-type semiconductor substrate 18, at the entire back surface thereof. The order of forming the n⁺-type FS layer 20 and the p⁺-type collector region 22 may be interchanged.

Next, the p⁺-type collector region 22 and the n⁺-type FS layer 20 are activated by a heat treatment (annealing). Next, the entire front surface of the substrate is covered with a surface protective film (not depicted) such as a polyimide film and then, the surface protective film is patterned to expose the emitter electrode 52 and each electrode pad.

Next, the back surface electrode 24 in contact with the p⁺-type collector region 22 is formed at the entire back surface of the semiconductor substrate (step S17: thirteenth process). Thereafter, the semiconductor wafer is cut (diced) into individual chips, thereby completing the IGBT 80 depicted in FIG. 1.

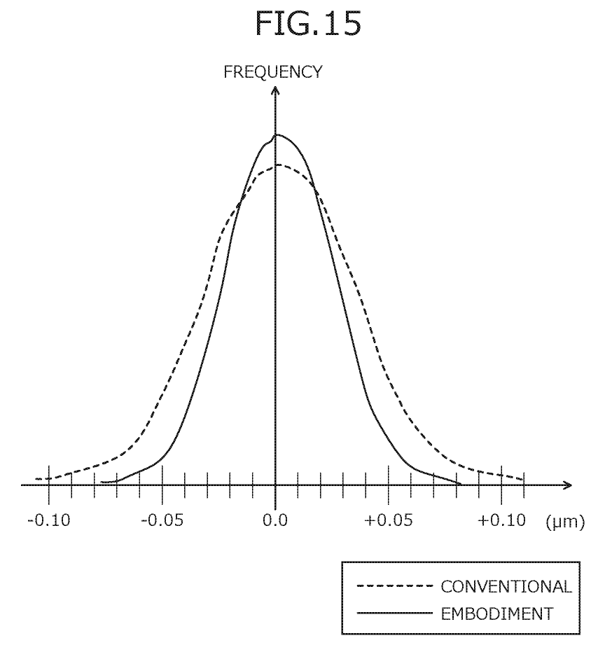

FIG. 15 is a graph depicting the frequency of misalignment of centers of the gate trenches in the semiconductor device according to the embodiment and the conventional semiconductor device. FIG. 15 depicts the accuracy of the position of the contact vias 68 when an i-line (spectral line having a wavelength of 365 nm) exposure machine is used and depicts the frequency of positional deviation of the centers of the contact vias 68 from the centers of two adjacent gate trenches. Here, a case where the width (cell pitch) between the centers of the gate trenches 40 is 2 μm and the width between the gate trenches 40 is 1 μm is depicted. In FIG. 15, a horizontal axis indicates a distance x between a center T2 of the contact vias 68 and a center T1 between two adjacent gate trenches, in units of μm (see FIG. 21). Here, the + side and the − side are directions depicted in FIG. 21. A vertical axis represents frequency.

As depicted in FIG. 15, in the embodiment, it is understood that the variation in the positional deviation of the contact vias 68 with respect to the positions of the gate trenches 40 is improved as compared with the related art. In particular, in the embodiment, there is almost no deviation of ±0.08 μm or more. Since the improvement of the positional deviation accuracy variation affects the distribution of the p⁺⁺-type contact regions 16 immediately below the contact vias 68, it also affects the concentration variation of the p-type base region 14 of the channel into which a part of the p⁺⁺-type contact regions 16 is diffused. Therefore, the improvement of the variation in the positional deviation accuracy leads to a reduction of the variation in the threshold voltage (Vth).

As described above, according to the embodiment, the oxide film is provided on the gate electrodes and the n⁺-type emitter regions, and the silicon nitride film is provided on the oxide film. Due to the silicon nitride film, even when the positional accuracy of the photoresist at the time of forming the contact vias and at the time of forming the contacts is insufficient, the contact vias may be formed between the gate trenches in a self-aligned manner without short-circuiting to the gate trenches, and it is possible to reduce the deterioration of the positional accuracy of the contact vias and the occurrence of fluctuation of characteristics.

In the above description, the present disclosure may be variously modified within a range not departing from the gist of the present disclosure, and in each of the embodiments described above, for example, dimensions, dopant concentrations, and the like of regions are variously set according to necessary specifications and the like. In the embodiments of the present disclosure, while a trench IGBT has been described as an example, the present disclosure is not limited hereto and is applicable to semiconductor devices having various configurations, such as a MOS semiconductor device including a trench metal oxide semiconductor field effect transistor (MOSFET).

According to the disclosure, the oxide film is provided on the gate electrodes and the second semiconductor regions (n⁺-type emitter regions) of the first conductivity type, and the silicon nitride film is provided on the oxide film. Due to the silicon nitride film, even when the positional accuracy of the photoresist at the time of forming the contact vias and at the time of forming the contacts is insufficient, the contact vias may be formed between the gate trenches in a self-aligned manner without short-circuiting to the gate trenches and it is possible to reduce the deterioration of the positional accuracy of the contact vias and the occurrence of fluctuation of characteristics.

According to the semiconductor device and the method of manufacturing a semiconductor device according to the present disclosure, it is possible to form the contact vias between the gate trenches in a self-aligned manner even when the positional accuracy of the photoresist at the time of forming the contacts is insufficient.

As described above, the semiconductor device and the method of manufacturing a semiconductor device according to the present disclosure are useful for power semiconductor devices used in power converting equipment such as inverters, power supply devices of various industrial machines, an igniter of an automobile, or the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having a first surface and a second surface opposite to each other; a first semiconductor region of a second conductivity type, provided at the first surface of the semiconductor substrate, the first semiconductor region having a first surface and a second surface opposite to each other, the second surface thereof facing the semiconductor substrate; a plurality of second semiconductor regions of the first conductivity type, selectively provided in the first semiconductor region, at the first surface thereof; a plurality of trenches penetrating through the first semiconductor region and the plurality of second semiconductor regions and reaching the semiconductor substrate; a plurality of gate dielectrics provided in the plurality of trenches, respectively, along bottom surfaces and sidewalls of the plurality of trenches; a plurality of gate electrodes provided on the plurality of gate dielectrics in the plurality of trenches, respectively; an oxide film covering the plurality of gate electrodes and the plurality of second semiconductor regions; a silicon nitride film provided on the oxide film; an interlayer dielectric film provided on the silicon nitride film; a plurality of contact vias penetrating through the oxide film, the silicon nitride film, and the interlayer dielectric film, and reaching the first semiconductor region; a barrier layer provided on sidewalls and bottom surfaces of the plurality of contact vias; a metal plug layer provided in the plurality of contact vias and in contact with the barrier layer; a first electrode provided on surfaces of the metal plug layer and the interlayer dielectric film; and a second electrode provided at the second surface of the semiconductor substrate.

2. The semiconductor device according to claim 1, wherein
each of the plurality of gate electrodes has a portion that protrudes in a thickness direction of the semiconductor device from the plurality of second semiconductor regions toward the first electrode, and that is covered by the silicon nitride film.

3. A method of manufacturing a semiconductor device, the method comprising:
preparing a semiconductor substrate of a first conductivity type, the semiconductor substrate having a first surface and a second surface opposite to each other; as a first process, forming a plurality of trenches in the semiconductor substrate, at the first surface thereof; as a second process, forming a plurality of gate dielectrics in the plurality of trenches, respectively, along bottom surfaces and sidewalls of the plurality of trenches; as a third process, forming a plurality of gate electrodes on the plurality of gate dielectrics in the plurality of trenches, respectively; as a fourth process, selectively forming a first semiconductor region of a second conductivity type, at the first surface of the semiconductor substrate, the first semiconductor region having a first surface and a second surface opposite to each other, the second surface facing the semiconductor substrate; as a fifth process, selectively forming a plurality of second semiconductor regions of the first conductivity type, in the first semiconductor region, at the first surface thereof; as a sixth process, forming an oxide film covering the plurality of gate electrodes and the plurality of second semiconductor regions; as a seventh process, forming a silicon nitride film covering the oxide film; as an eighth process, forming an interlayer dielectric film covering the silicon nitride film; as a ninth process, forming a plurality of contact vias penetrating through the interlayer dielectric film and the silicon nitride film and reaching the first semiconductor region; as a tenth process, forming a barrier layer at sidewalls and bottom surfaces of the plurality of contact vias; as an eleventh process, forming a metal plug layer in contact with the barrier layer in the plurality of contact vias; as a twelfth process, forming a first electrode at surfaces of the metal plug layer and the interlayer dielectric film; and as a thirteenth process, forming a second electrode at the second surface of the semiconductor substrate.

4. The method according to claim 3, wherein
the third process includes forming the plurality of gate electrodes so that each of the plurality of gate electrodes has a protruding portion that protrudes in a thickness direction of the semiconductor device from the plurality of second semiconductor regions toward the first electrode, and the seventh process includes forming the silicon nitride film so as to cover the protruding portions of the plurality of gate electrodes.

5. The method according to claim 3, further comprising as a fourteenth process, forming a thermal oxide film and a nitride film on the semiconductor substrate before the first process.
